(19) United States
(12) Patent Application Publication
(10) Pub. No.: US 2009/0296334 A1
(43) Pub. Date: Dec. 3, 2009

(54) TRANSMISSION MODULE ON DESKTOP MONITOR

(76) Inventors: James CHU, Taipei (TW); H.C. Ho, Taipei (TW)

Correspondence Address: YOUNG & THOMPSON, 209 Madison Street, Suite 500, ALEXANDRIA, VA, 22314, US

(21) Appl. No.: 12/127,285

(22) Filed: May 27, 2008

(51) Int. Cl. H05K 7/00

(52) U.S. Cl. 361/679.22

(57) ABSTRACT

A transmission module on desktop monitor includes at least a set of conversion control chips, one of which being mounted on a desktop monitor while the other one being mounted on a notebook computer or a personal computer; a transmission interface connected to each of the two conversion control chips for transmitting signals on the conversion control chips; and one or more of a sound output port, a sound input port, a microphone port, a plurality of USB ports, a set of P/S ports, a monitor connection port, a serial port, a parallel port, and a 1394 port, being provided on the desktop monitor and electrically connected to the conversion control chip mounted on the desktop monitor. In this manner, I/O interfaces on the notebook computer or the personal computer are extended to the desktop monitor.

### FIELD OF THE INVENTION

The present invention relates to a transmission module, and more particularly to a transmission module on desktop monitor.

### BACKGROUND OF THE INVENTION

Please refer to FIGS. 1 and 2, in which a conventional technical means for connecting a notebook computer to a desktop monitor is shown. As shown, the means includes a base 1, on which an upward protruded rib 11 is provided. The rib 11 has a plurality of terminals 12 mounted along outer wall surfaces thereof to form a male seat 13 on the base 1. On the other hand, a circuit baseboard 2 is provided at an underside of a notebook computer, and includes a downward opened cavity 21. The cavity 21 has a plurality of electric terminals 22 provided on sidewalls thereof corresponding to the terminals 12 to form a female seat 23. When it is necessary to use a desktop monitor, a user may stably position the notebook computer on the base 1 with the female seat 23 at the underside of the notebook computer aligned with and associated with the male seat 13 on the base 1. At this point, the terminals 12 on the male seat 13 are in contact with the electric terminals 22 on the female seat 23, allowing signals on the notebook computer to be sent out via the contacted terminals 12, 22. The base 1 is then electrically connected to a desktop monitor, so that images on the notebook computer may be displayed on the desktop monitor, and various kinds of external connection ports the same as those provided on the notebook computer are provided on the base 1, so that a user may connect personally preferred external input devices, such as keyboard and mouse, to the external connection ports on the base 1. With the mutually contacted terminals 12, 22 for signal transmission and the external devices connected to the base 1, the user may conveniently operate the notebook computer via the desktop monitor.

However, the base 1 occupies a quite large space and therefore does not meet the compactness and low weight requirements of people in the modern society. Moreover, since the base 1 could not be stored when it is not in use, it forms a spatial burden to a user.

It is therefore tried by the inventor to develop a transmission module on desktop monitor, so as to solve the problems in the prior art.

### SUMMARY OF THE INVENTION

A primary object of the present invention is to provide a transmission module on desktop monitor, so that various port signals may be transmitted from a notebook computer or a personal computer to a desktop monitor, and a user may directly connect different external devices to the desktop monitor without occupying additional space.

Another object of the present invention is to provide a transmission module on desktop monitor, so that I/O interfaces on a notebook computer or a personal computer may be extended to and electrically connected to a desktop monitor via various types of transmission interfaces, such as a USB transmission interface, a 1394 transmission interface, an IrDA (Infrared Data Association) transmission interface, or a Bluetooth transmission interface, so that the notebook computer or the personal computer and the desktop monitor may be used in a more convenient manner.

A further object of the present invention is to provide a transmission module on desktop monitor, so that the desktop monitor may be conveniently used to supply power to or charge a notebook computer via a conversion control chip mounted on the desktop monitor.

To achieve the above and other objects, the transmission module on desktop monitor according to the present invention includes at least a set of conversion control chips, one of which being mounted on a desktop monitor while the other one being mounted on a notebook computer or a personal computer; a transmission interface connected to each of the two conversion control chips for transmitting signals on the conversion control chips; and one or more of a sound output port, a sound input port, a microphone port, a plurality of USB ports, a set of P/S ports, a monitor connection port, a serial port, a parallel port, and a 1394 port, being provided on the desktop monitor and electrically connected to the conversion control chip mounted on the desktop monitor. In this manner, I/O interfaces on the notebook computer or the personal computer are extended to the desktop monitor.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of a conventional technical means for connecting a notebook computer to a desktop monitor;

FIG. 2 is a sectional view of the conventional technical means for connecting a notebook computer to a desktop monitor;

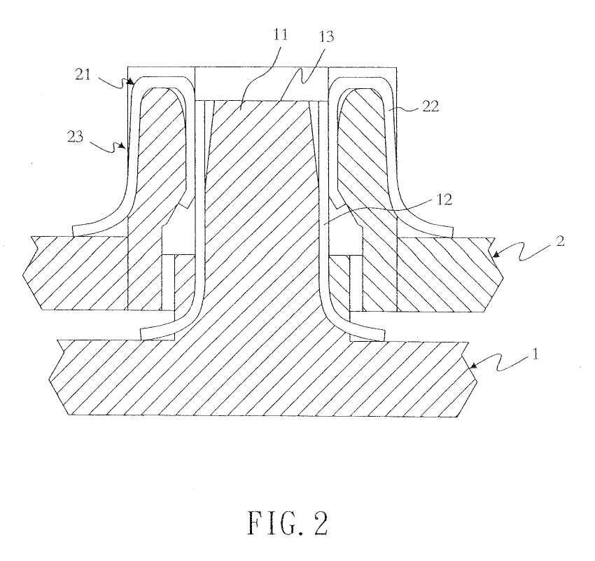

FIG. 3 is a block diagram of the transmission module on desktop monitor according to the present invention;

FIG. 4 is a fragmentary rear perspective view of a desktop monitor with the transmission module of the present invention provided thereon; and

FIG. 5 is a top view showing the use of the transmission module on desktop monitor according to the present invention.

### DETAILED DESCRIPTION OF THE PREFERRED EMBODIMENTS

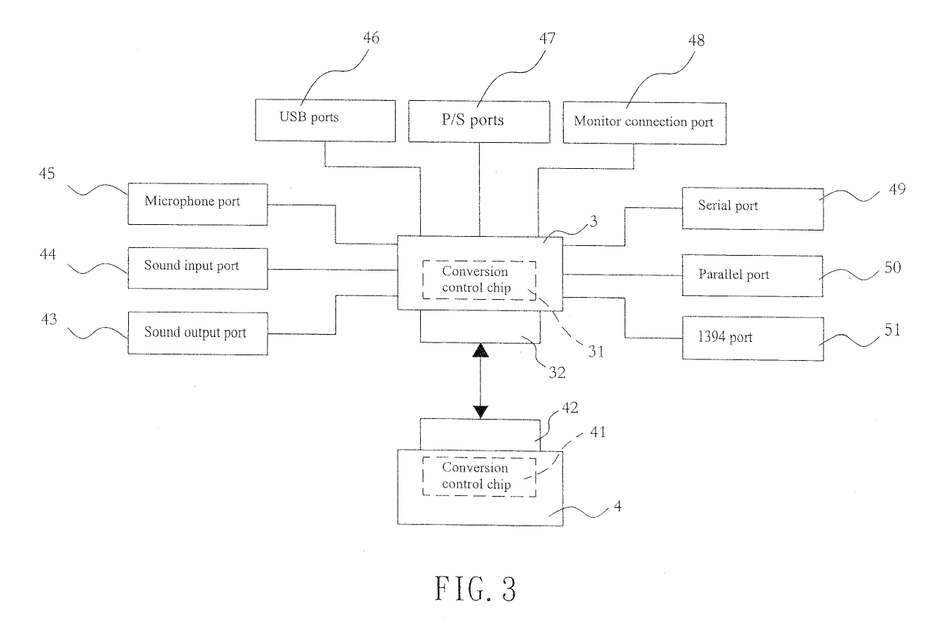

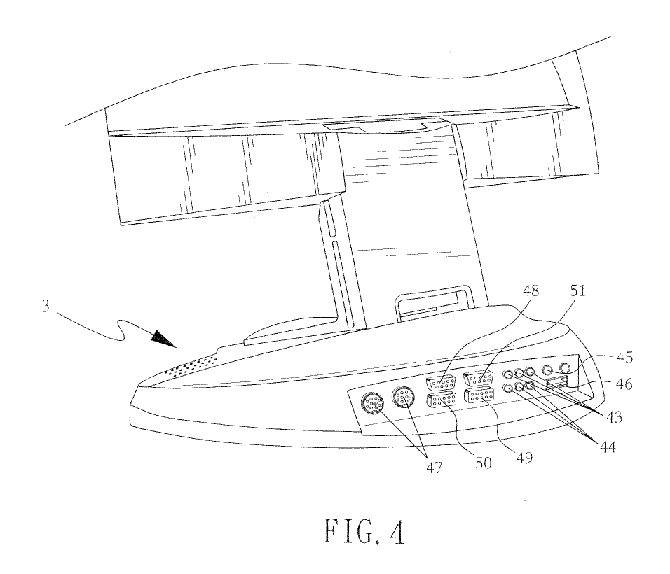

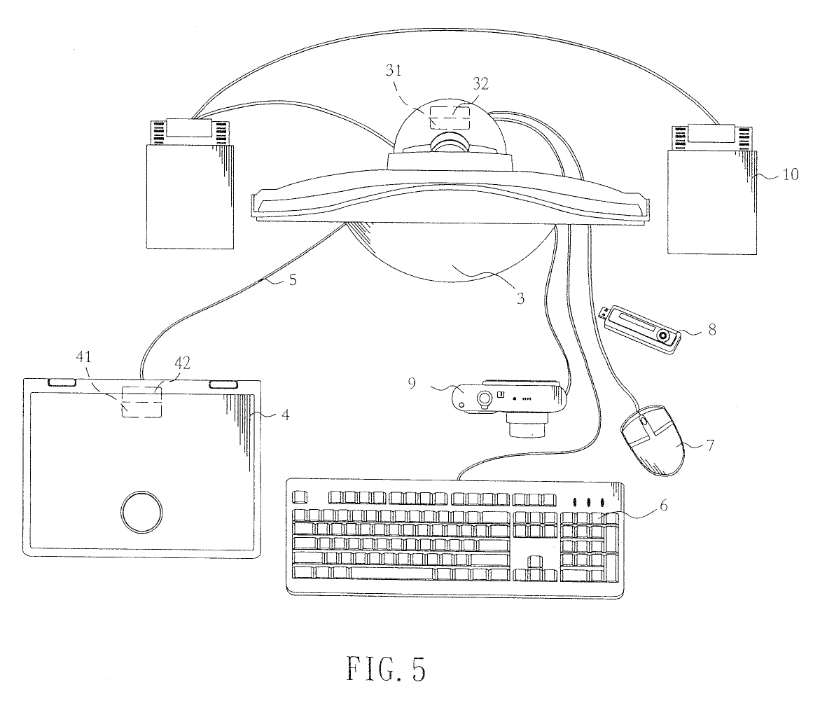

Please refer to FIG. 3 that is a block diagram of a transmission module on desktop monitor according to the present invention, to FIG. 4 that is a fragmentary rear perspective view of a desktop monitor with the transmission module of the present invention provided thereon, and to FIG. 5 that is a top view showing the use of the transmission module on desktop monitor according to the present invention. As shown, the present invention includes a set of two conversion control chips 31, 41 internally mounted on a desktop monitor 3 and a notebook computer 4 or a personal computer (not shown), respectively. The conversion control chips 31, 41 are respectively connected to a transmission interface 32, 42, such that signals may be transmitted between the desktop monitor 3 and the notebook computer 4 via the transmission interfaces 32, 42.

The present invention is characterized in the conversion control chips 31, 41. The notebook computer 4 has a group of input/output (I/O) interfaces, including a sound output port 43, a sound input port 44, a microphone port 45, a plurality of USB (universal serial bus) ports 46, a set of P/S (parallel/serial) ports 47, a monitor connection port 48, a serial port 49, a parallel port 50, and a 1394 port 51. The conversion control chip 41 on the notebook computer 4 is able to convert the above listed I/O interfaces into a specific transmission specification, so that signals may be transmitted from the I/O interfaces on the notebook computer 4 via the transmission interface 42 to the transmission interface 32 on the desktop monitor 3. The signals received via the transmission interface 32 are then converted by the conversion control chip 31 back into the signals of the sound output port 43, the sound input port 44, the microphone port 45, the plurality of USB (universal serial bus) ports 46, the set of P/S (parallel/serial) ports 47, the monitor connection port 48, the serial port 49, the parallel port 50, and the 1394 port 51.

The transmission interface 42 may be a wired transmission interface, such as, for example, a USB transmission interface, a 1394 transmission interface, or an HDMI (High-Definition Multimedia Interface) digital high bandwidth specification transmission interface; or a wireless transmission interface, such as, for example, an IrDA (Infrared Data Association) transmission interface, or a Bluetooth transmission interface; a cableless ultra wideband (UWB) USB transmission unit; or a wired or wireless Ethernet transmission interface of an IEEE802.15, IEEE802.11x, WiFi specification, etc.

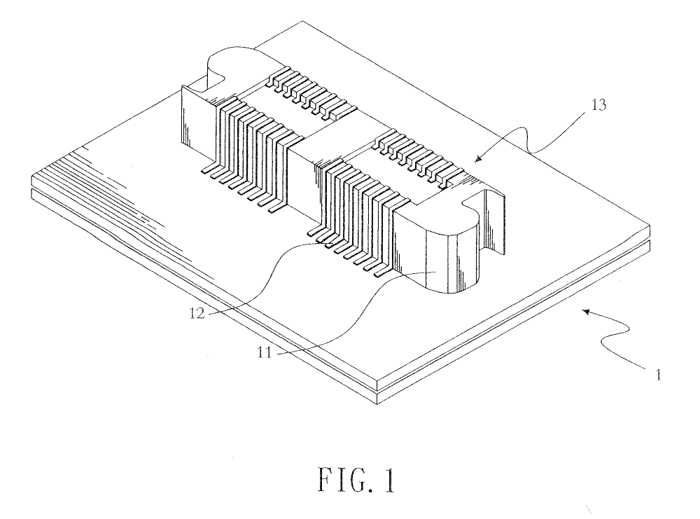

In the present invention, ports 43, 44, 45, 46, 47, 48, 49, 50, and 51 the same as those on the notebook computer 4 are also provided on the desktop monitor 3. In this manner, the I/O interfaces on the notebook computer 4 or a personal computer (not shown) are extended to the desktop monitor 3 without occupying additional space and a user may more conveniently connect the notebook computer 4 to the desktop monitor 3. With the present invention, a user may directly connect personally preferred keyboard, mouse, and/or other input interfaces to the desktop monitor for operating the notebook or personal computer, and the conventional heavy base 1 as shown in FIG. 1 may be omitted. Moreover, the transmission module on desktop monitor according to the present invention may also be used to supply power to and charge the notebook computer 4.

As can be seen from FIG. 5, a user needs only to connect the transmission interfaces 32 and 42 to each other via a cable 5, and the I/O interfaces of the notebook computer 4 or a personal computer (not shown) can be extended via the internal conversion control chip 41 to the desktop monitor 3, allowing a user to directly connect different external devices, such as a keyboard 6, a mouse 7, a USB flash drive 8, a digital camera 9, and/or a set of loud speakers 10 to the desktop monitor 3 for operation. And, so long as a user has a desktop monitor 3, the user may freely the desktop monitor 3 simply by connecting the notebook computer 4 or the personal computer to the desktop monitor 3 via the cable 5.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A transmission module on desktop monitor, comprising:
a set of two conversion control chips, one of which being mounted on a desktop monitor, while the other one being mounted on a notebook computer or a personal computer;
a transmission interface connected to each of the two conversion control chips, so as to transmit signals on the two transmission chips; and
one or more of a sound output port, a sound input port, a microphone port, a plurality of USB ports, a set of P/S ports, a monitor connection port, a serial port, a parallel port, and a 1394 port, being provided on the desktop monitor at predetermined positions and electrically connected to the conversion control chip mounted on the desktop monitor.

2. The transmission module on desktop monitor as claimed in claim 1, wherein the transmission interface is a wired transmission interface.

3. The transmission module on desktop monitor as claimed in claim 2, wherein the transmission interface is a USB transmission interface.

4. The transmission module on desktop monitor as claimed in claim 2, wherein the transmission interface is a 1394 transmission interface.

5. The transmission module on desktop monitor as claimed in claim 2, wherein the transmission interface is an HDMI digital high bandwidth specification transmission interface.

6. The transmission module on desktop monitor as claimed in claim 1, wherein the transmission interface is a wired local area network (LAN IEEE802.3) transmission interface.

7. The transmission module on desktop monitor as claimed in claim 1, wherein the transmission interface is a wireless transmission interface.

8. The transmission module on desktop monitor as claimed in claim 7, wherein the transmission interface is an IrDA transmission interface.

9. The transmission module on desktop monitor as claimed in claim 7, wherein the transmission interface is a Bluetooth transmission interface

10. The transmission module on desktop monitor as claimed in claim 7, wherein the transmission interface is a cableless UWB USB transmission unit.

11. The transmission module on desktop monitor as claimed in claim 7, wherein the transmission interface is a wireless LAN IEEE802.11x transmission interface.
